(19) United States
(12) Patent Application Publication
(10) Pub. No.: US 2013/0195231 A1
(43) Pub. Date: Aug. 1, 2013

(54) AUTOMATIC GAIN CONTROL

(71) Applicant: TEXAS INSTRUMENTS INCORPORATED, Dallas, TX (US)

(72) Inventors: Peter Hearne, Buckinghamshire (GB); Richard Simpson, Bedford (GB); Pulkit Khandelwal, Buckinghamshire (GB)

(73) Assignee: TEXAS INSTRUMENTS INCORPORATED, Dallas, TX (US)

(21) Appl. No.: 13/755,653

(22) Filed: Jan. 31, 2013

(30) Foreign Application Priority Data
Jan. 31, 2012 (GB) 1201581.4

(51) Int. Cl. H03G 3/30

(52) U.S. Cl. CPC H03G 3/3078
USPC 375/345

(57) ABSTRACT

The present invention relates to receiver circuitry and methods for the reception of serial data and in particular to the setting of a gain within such circuitry so that the data may be successfully received. It provides a data receiver that comprises an amplifier connected to receive a data waveform and to amplify it, the amplifier having a controllable gain, a test sampler connected to sample the amplified data waveform to a 1 or 0 based on a reference level, to provide a set of test bits and a gain adjusting circuit responsive to the number of test bits that are one of 1 or 0 in the set of the test bits.

This application claims priority under 35 USC §119(e)(1) of European Application Number GB 1201581.4, filed on Jan. 31, 2012.

The present invention relates to receiving high speed data signals.

### BACKGROUND

The reception of data at high data rates, for example, 10 Gbs⁻¹ and above, provides, as is known in the art, various challenges. One of these is that the signal level received for a particular bit of the incoming bitstream is dependent on the history of the preceding bits. For example a 1 preceded by a 0 will have a lower level (assuming 1 is represented by a high level) than a 1 preceded by another 1. (This is known as “inter-symbol interference”.) Earlier bits than the previous bit also have an influence on the level of the present bit but this influence, while usually smaller than that of the previous bit, is often significant. A future bit (i.e. the next bit to be received after the present one) can also affect the level of the present bit. If the traces of an incoming bitstream data waveform are divided into segments one UI long (UI=“unit interval”—the duration of an undistorted one bit pulse), and those segments are overlaid, the well-known “eye diagram” results. Typical examples of such an eye diagram are shown in FIGS. 1A and 1B; the space in the centre free from traces is called the “eye”. FIG. 1A shows the eye diagram where the previous bit is a 1, in this case the influence of the previous bit is quite strong. The eye of interest 45 is the middle and left one of the three large spaces, The corresponding full eye diagram is FIG. 1B and includes both the traces of FIG. 1A and those for the case where the previous bit is 0, which are those of FIG. 1A reflected through the horizontal axis. Thus there are two eyes 45, 46 of interest. Note that this diagram shows traces extending over a longer period than an interval of 1 UI; in the diagram 1 UI is 48 of the units marked on the horizontal time axis. (The other markings on the diagram are explained below.)

A typical data receiver known in the art is shown in FIG. 2. The incoming signal 10 is received at input terminal 11. For simplicity of illustration this is shown single ended but usually the signal will be a differential one. The signal 10 is first amplified to a level suitable (signal 14) for processing by the rest of the circuit by a variable gain amplifier 12.

The next stage is for the amplified data waveform 17 to be sampled by sampling block 18, a partial equalisation having been applied by an analogue equaliser 15 (described below). The sampling block comprises several samplers 19 in parallel. Each sampler 19 (See FIG. 3) comprises a comparator 20 connected to compare the level of the data waveform 17 to a respective reference level 21. The output of each comparator 20 is latched by a latch 22 at a time determined by a local clock signal 23 generated by a common local oscillator 24. The latch has an output making the 1 or 0 valued sample taken available to the rest of the receiver circuit.

In this example, two of the samplers 19 are used to take the data. Sampler 19_{d1} is used to take the data when the previous bit is a 1. Its reference level 21_{d1} is set to be a level midway up the upper eye 45 (the one shown in FIG. 1A and identified above in relation thereto). Sampler 19_{d0} is used to take the data when the previous bit is a 0. Its reference level 21_{d0} is set to be a level midway up the lower eye 46. In fact both samplers are used to take a sample in each UI interval but a multiplexer 26 is used to select between them on the basis of the value of the preceding bit. The preceding bit is stored in the first bit 27₁ of shift register 28. The output of the multiplexer is the input to the first bit of the shift register and the shift register 28 is shifted one bit each UI, again under the control of the local clock signal 23.

The gain of amplifier 12 is controlled by a gain control signal 13. A gain controller 50 calculates this by inspecting the output of an additional sampler 19_{gain}, which samples the amplified and partially equalised data waveform 17 comparing the level of that waveform to a predefined target reference level V_{target}. If the waveform 17 is above the reference level Vtarget, the test sample will be a 1 and a 0 if the waveform 17 is below Vtarget.These test samples are held in a shift register 29. A particular one of the test samples along the shift register (it does not matter which) is output to the gain controller along with the corresponding data sample that was taken at the same time as the test sample (so in this example the two bits are at the same position along their respective shift registers). That data sample and the future and previous data samples are also compared to the code 111 by code matcher 51 and whether or not they form the code is indicated to the gain controller. The gain controller only acts in cases where the code 111 is matched. When this occurs the test samples are used to adapt the variable gain amplifier. If the test sample is 1, then the waveform 17 is below the reference level Vtarget so the gain needs to be increased and vice versa. This keeps the 111 trace at the level of the target reference level; the 111 trace is the one that has the highest level and so is a useful measure of the amplitude of the data waveform. The gain is not adjusted at each bit but only from time to time, for example every few thousand samples.

The amplified output signal 14 of the variable gain amplifier 12 is equalised (before sampling) by an analogue equaliser 15. In this example the equaliser has a high-pass characteristic with the cut-off frequency being around the highest frequency in the incoming data signal (which is equal to half the data rate) with the gain in the stop band being set by an equalisation control signal 16. While “stop band” is the usual terminology it could be misleading in this case as the objective is not to eliminate those frequencies from the signal but to boost the higher frequencies relative to them, since the higher frequencies will have been attenuated in the transmission line over which the data signal was transmitted. As is known in the art, the analogue equaliser is controlled by a feedback loop based on samples 47 older than those used by the DFE 30 (described below) as is known in the art. Decisions (taken by block 48) based on those samples are used to adjust the equalisation control signal. Again the gain is only adjusted from time to time.

FIG. 4 is a circuit diagram of an equivalent circuit for the analogue equaliser 15. This is a simple RC filter that has a capacitor connected between its input 60 and its output 61 and a resistor 65 is connected between the output and ground 64. A variable resistor 63 connected in parallel with the capacitor has its resistance controlled by the equalisation control signal 16 so when its resistance is high the gain in the stop band is low and when its resistance is low the gain in the stop band is higher. This equaliser only partially reverses the effects of the channel along which the data waveform was transmitted (a DFE described below also provides some equalisation).

The local oscillator 24 is a variable oscillator and is controlled by a clock recovery circuit 25, which adjusts the frequency and phase of the local clock signal 23. Many techniques are known in the art for keeping the local clock signal synchronised with the data waveform. Some of these techniques work off the analogue data waveform 17 such as in a phase locked loop, while others utilise digital samples 52 of the waveform taken by the data samplers (and/or by additional samplers).

This clock recovery circuit 25 operates to provide a timing point for the sampling of the data that is near the centre of the eye since at that point the traces for which the current bit is a 1 or 0 pass respectively above and below the eye.

In this example the content of the shift register 28 is also used by a decision feedback equaliser DFE 30. This uses the recently taken bits to set the reference levels 21_{d1}and 21_{d0} of the data samplers 19_{d1} and 19_{d0}. In a sense the multiplexer 26, being responsive to the most recent bit 27₁, is part of this equalisation process because it provides a gross adjustment of the data sampling reference level by choosing between the two samplers 19_{d0} and 19_{d1}. The DFE inspects the value of each of the recent most n samples (in this example n=3 so the DFE inspects 27₁, 27₂ and 27₃ in the shift register). In response to that it adds together respective n reference level contributions h₁, h₂ and h₃ that are values of the contributions of those previous bits to the level in the current bit and removes the effect of their interference on the current bit as is known in the art. The contribution levels may for example be predetermined by design or by experimental measurements. Again the DFE only adjusts the reference levels 21_{d1}, 21_{d0} from time to time.

The inventors have noticed a problem with gain control in this circuit arrangement. In the steady state the control of the gain of the amplifier described above works adequately. However there can be a problem if the incoming data waveform is initially quite small or the VGA is not set correctly relative to the waveform. This can result in the data samplers 19_{d1} and 19_{d0} deciding incorrectly that the data is 1 and 0 alternately (i.e. 10101010 . . . ) that is because if the signal is small it will be near 0V and sampler 19_{d1} will decide that the signal is a 0 with the result that sampler 19_{d0} is used next which will decide that the signal is 1 with the result that 19_{d1} is used next and so on. The gain control method described above cannot come into operation in this situation because it waits for the 111 code, which, of course, does not occur. This would result in the variable gain amplifier stopping adapting and locking at an incorrect setting.

Data dependent variable gain adaptation can be very accurate but does rely on good data recovery which in turn requires a reasonably correct VGA gain value. This present invention details how to avoid this circular dependency.

### SUMMARY OF THE INVENTION

The present invention provides an alternative method of adjusting the gain of the analogue amplifier of a data receiver. While the method may not be as accurate as other methods, for example, that described above, it should cope with data waveforms with small amplitude. Therefore it can be used during an initial period, and if greater accuracy is required a different method can be used after the initial period.

According to the present invention there is provided a method performed in a data receiver for a data waveform of adjusting the gain applied to the data waveform by an amplifier, and a data receiver, as defined in the appended claims.

### BRIEF DESCRIPTION OF THE DRAWINGS

Examples of the invention will now be described, with reference to the accompanying drawings, of which:

FIGS. 1A and 1B are graphs each showing superposed traces of segments of a data waveform (Prior Art),

FIG. 2 is a block diagram of a typical data waveform receiver circuit (Prior Art),

FIG. 3 is a block diagram of a data sampler used in the circuit of FIG. 2,

FIG. 4 is an equivalent circuit of an analogue equaliser used in the circuit of FIG. 2, and

FIG. 5 is a block diagram of a data waveform receiver circuit in accordance with the invention.

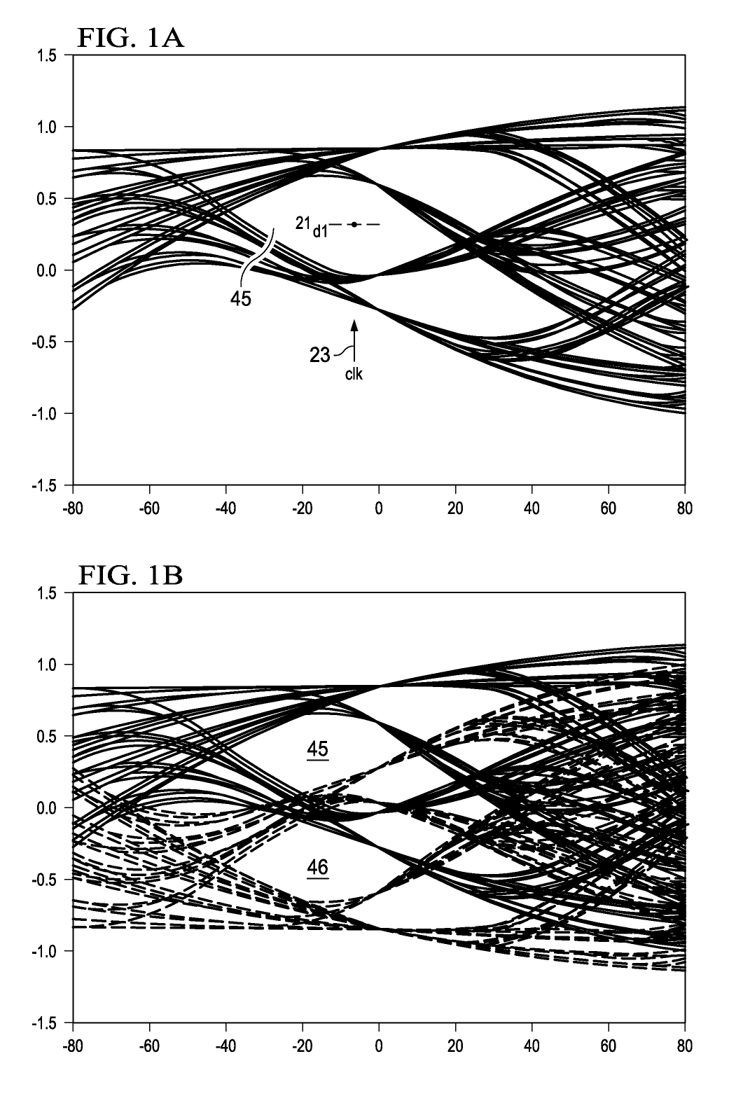

### DETAILED DESCRIPTION

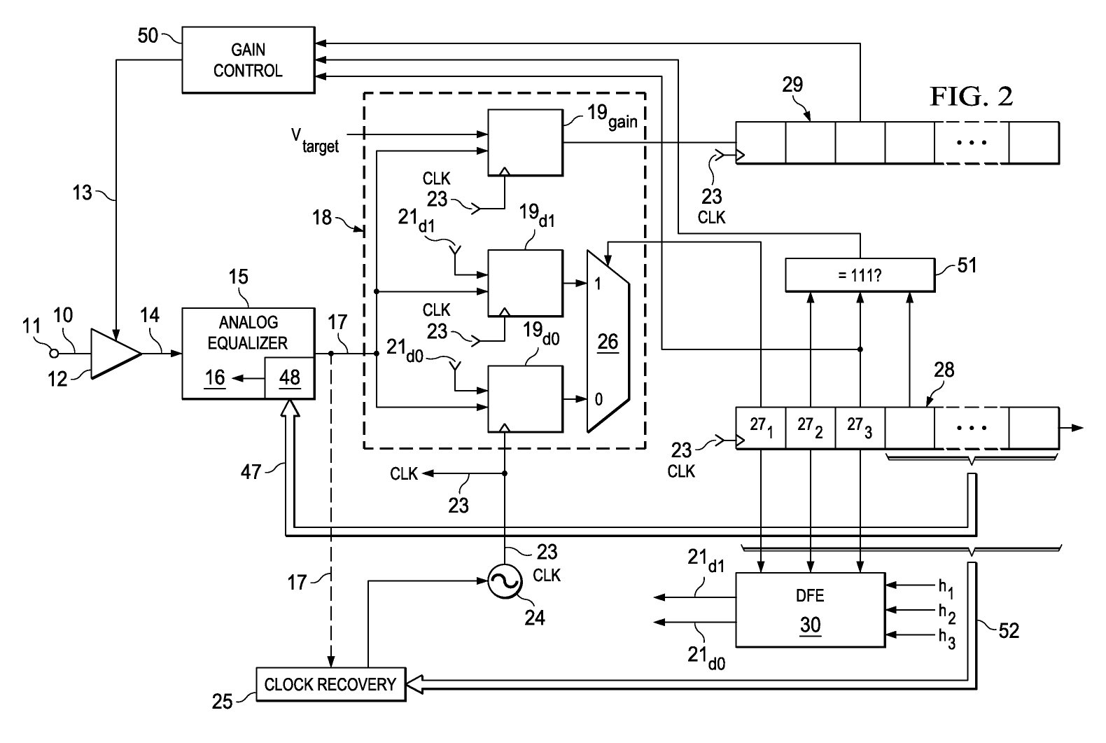

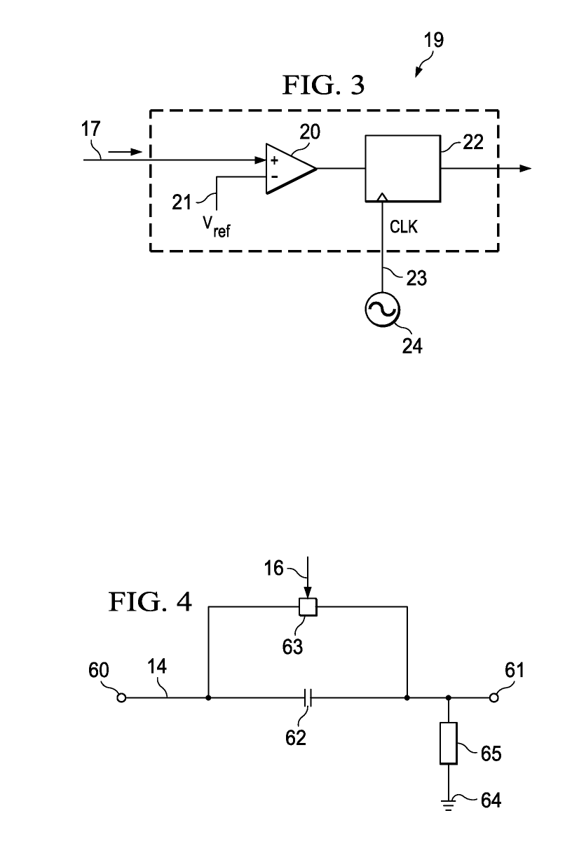

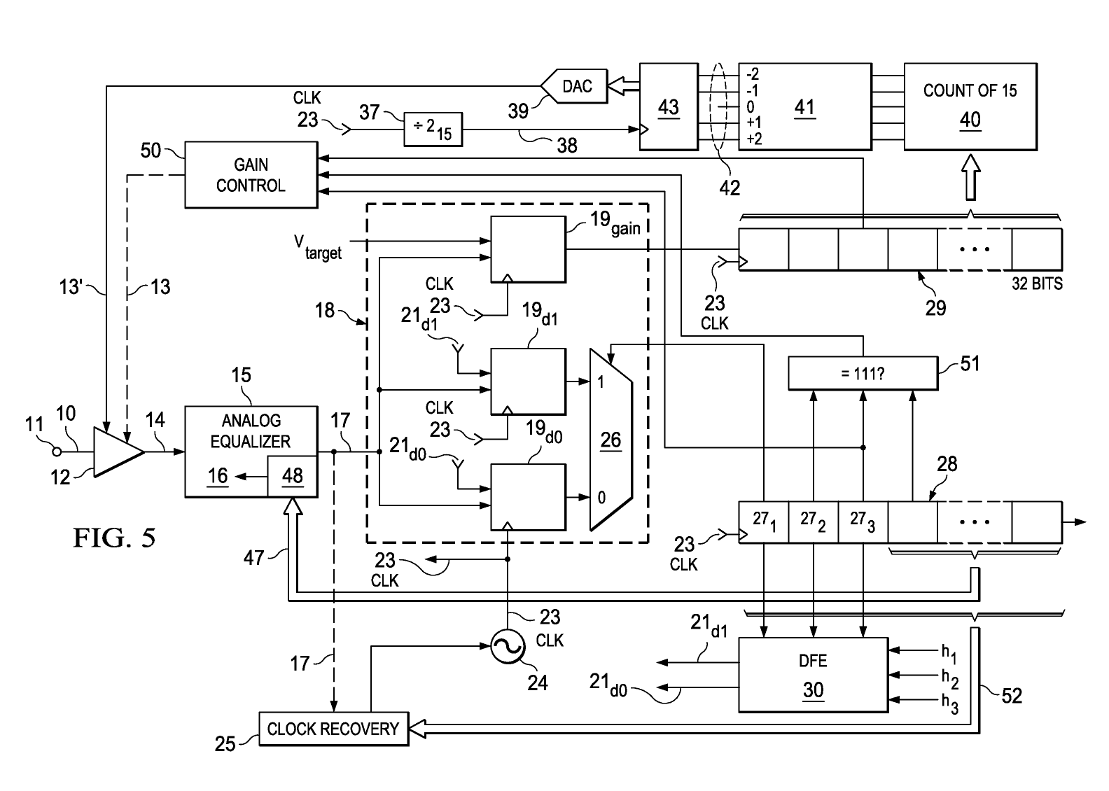

FIG. 5 is a block diagram of an example of a circuit according to the invention. Generally this example is similar to the receiver circuit described above with reference to FIGS. 2 to 4, with similar reference numerals being used for similar parts. However in this example the alternative method of adjusting the gain of the variable gain amplifier 12 is provided, as follows.

The data waveform samples are, as described above, collected in turn in the shift register 28. Again a gain control sampler 19_{gain} is provided to take test samples of the waveform for the purpose of making decisions about the gain to be applied by the amplifier 12 that amplifies the incoming data waveform, and again it is provided with a reference level V_{target} that is at the level desired for 111 data patterns (those being the previous, present and next bits). The additional shift register 29 is again provided to collect the output of the gain control sampler 19_{gain}. However in this example the shift register stores 32 consecutive samples. When a word of 32 samples from that sampler has been collected it is presented to a population counter 40. This circuit counts the number of is in the 32 bit word. (Population counter circuits are well known in the art, so the details are not described here.) The count of 1s is output as a binary 5 bit word which is then converted by a cross coder 41 to increment and decrement control signals according to the following table:

TABLE 1

| Population count | Increment instruction |
|---|---|
| >=4 | Decrement by 2 |
| 3 | Decrement by 1 |
| 2 | No change |
| 1 | Increment by 1 |
| 0 | Increment by 2 |

These signals are presented as a one of many active signals on four parallel lines 42 to a gain level register 43. (If the output is no change then no signal is active.) These lines control the incrementing or decrementing of a gain level register 43 causing it to increment or decrement by the number of units shown in Table 1. The incrementing or decrementing takes place every 2¹⁵ UI timed by a clock signal 38 divided from the local clock signal 33, by divider 37. The word in the gain level register is converted to a gain control analogue signal 13′ by a digital to analogue converter 39, which signal then controls the gain of variable gain amplifier 12. As will be apparent to those skilled in the art it may well be possible to reduce the number of gates used in logic blocks 40 and 41 by combining their functions into a single block and in such a joint logic block the count might not appear as an explicit signal.

This method avoids the adaptation lockup condition mention previously as it does not rely on the data from the data samplers being correct. Instead it looks exclusively at the 19gain sampler to adapt the variable gain amplifier. This method works as follows. Assuming random data the pattern ‘111’ will appear ⅛ of the time in the data and creates the maximum amplitude of the signal. When the 19gain sampler is adjusted to be at the mid-point of this maximum amplitude distribution (the target) the waveform will be above this 19gain sampler (giving an output of 1) half of this ⅛ (equals 1/16th) and the other half of the ⅛ plus the other ⅞ths (equal to 15/16ths) it will be below. We can therefore set the 19gain sampler to be at the correct value by adjusting the gain until this sampler outputs a 1 1/16th of the time. The key here is that this is performed independently of data being sliced correctly.

By looking at a set of 32 bits output from the 19gain sampler, 29 in FIG. 5, when the gain is set correctly one should see two is in this word.

The other lines in the table follow. If more is than that are produced then the gain of the amplifier is too high and so is reduced and if fewer then it is increased, which is what the decrements and increments, respectively, in Table 1 cause. The larger increments of 2 units in the value of the gain word are not essential but they do help to increase the speed with which the gain is changed to the right level, with the smaller increments providing finer adjustment when the level is nearly right.

Not all 111 traces are exactly equal in level. For example a 1111 trace (two previous, current and future bit all being 1) will without equalisation be slightly higher than a 0111. Equalisation should reduce the difference between them but if not then the difference between them will appear as noise to the method and so the method will not set the level of the gain any more accurately than allowed by that noise.

The number of 1s and 0s expected at test sampler 19_{gain} could be worked out on the basis of longer codes than the 111 mentioned above, e.g. 1111, but preferably that should take into account whether, for example, the 1111 code trace is expected to be at a different level from that of 0111.

Shorter codes could also be used but accuracy will be reduced since the noise in their trace levels due to bits earlier than those of the code will be significant.

Selecting a reference level 21_{gain} based on a code for an extreme trace may be preferable for the following reasons. First it makes the arithmetic of how many 1s to expect in a set easy to work out. Relatedly, it means the expected number of is if the desired gain is achieved is clearly unambiguous—if the gain is too high the 111 trace and any other code trace exceeding V_{target} will produce more is than the expected number and if the gain is too small fewer than the expected number of 1s will occur. Similarly the particular problem noted above was that of there being too small an initial gain and the gain control feedback of the invention will not notice any change in the number of 1s generated by 19_{gain}, which will stay at 0 until the gain is almost correct.

The method could, however, also be used with the number of 1s and 0s expected based on a code having a non-extreme trace. Again accuracy of the gain level found could be reduced if the other codes have traces of not significantly different level and ambiguity could result if traces cross in the region of the sampling time of sample 19_{gain}.

The method could also be used on non-random data pattern, e.g. test patterns, with the expected number of 1s and 0s worked out appropriately.

In the above example the phase of the sampling time of sampler 19_{gain} is the same as that of the data sampler. This is not essential however and its phase could be offset.

It is to be noted that the chances of sampler 19_{gain} sampling a 1 or a 0 do not depend on the neighbouring test samples being taken by that sampler. Accordingly it is not essential that the test samples taken into account by population counter 40 do not need to be consecutive ones (i.e. ones separated by 1 UI as they are in the example of FIG. 5). Whether or not the test samples taken are consecutive care should be taken with not quite random data streams that the selection of samples taken into account does not introduce a bias from 50% for those bits being 1 or 0.

The set of test bits counted in the above example is 32. This is the preferred number where testing is based on a three bit code. Other numbers can be used but powers of two make the arithmetic easier. In the example a set of 16 test bits would have only one 1 expected and so would cause some fluctuation in the gain adjustment since the count of is in the set will quite often be zero or more than one for random data. For a set of 64 bits the expected number of 1s would be four, which may fluctuate less but one may wish to include more rows in the Table 1 leading to greater complexity of the circuit.

Once this method has brought the gain approximately to the right level, more accurate methods, for example that described in relation to FIG. 2 can be employed instead.

In a more detailed example of the invention similar to that of FIG. 5, a geared approach to the control of the amplifier gain is used. In this example the gain level register 43 is 14 bits long but only the most significant seven bits are applied to the DAC 39. Initially in a first mode or “gear” the increments and decrements of 1 are applied to the least significant bit of those seven most significant bits, with the increments of 2 causing a increment of 1 in the next most significant bit. This provides a rapid but not very accurate adjustment of the gain—not only are the steps in gain large they can be caused by random fluctuations in the number of is in the shift register 29. This adjustment mode or “gear” is applied for a period. Next a second mode or “gear” is applied for a period, in which the increments and decrements are applied to the next bits down in significance along the gain level register 14. Third and fourth gears are then applied for respective subsequent periods with the increments and decrements again being moved down one bit each time. So each gear has smaller increments and decrements than the last which allows for more accuracy and because they are applied to bits of less significance than those applied to the DAC 39 they filter out the changes causing random fluctuations in the number of is in the shift register 29.

In this more detailed example there are also a further four more gears, which uses the gain control method of FIG. 2. Here the gain controller comprises the gain level register 43 and the DAC 39 and increments and decrements a particular bit of the register in accordance with the method of testing corresponding data and gain test samples when the code received is 111 that was described above in relation to FIG. 2. In the fifth gear it increments and decrements the next bit down from that incremented and decremented by 1 in the fourth gear. In the sixth, seventh and eighth it increments and decrements the next bit down from that incremented and decremented in the previous gear.

1. A method performed in a data receiver for a data waveform of adjusting the gain applied to the data waveform by an amplifier, comprising:
providing a reference level,
sampling a set of test bits from the amplified waveform with respect to the reference level,
adjusting the level of the gain applied by the amplifier in response to the number of test bits in the set that have a first binary value.

2. A method as claimed in claim 1 wherein the sampling and adjusting is repeated.

3. A method as claimed in claim 1 wherein the reference level is a target level for a data waveform trace for a particular data code in the data waveform and the gain is adjusted taking into account the number of test bits of the set having the first binary value compared to the number of test bits in the set having the first binary value expected based on the frequency of the data code expected in the data waveform for that set.

4. A method as claimed in claim 3 wherein the data code is three bits long.

5. A method as claimed in claim 1 wherein the reference level is the target level for the data waveform for a data code having all the bits equal to the same binary value.

6. A method as claimed in claim 1 wherein reference level is the target level for the data waveform for a data code that results in the data waveform having a level at an extreme of those provided by codes of the same length.

7. A method as claimed in claim 1 wherein the test bits of the set are ones from consecutive unit intervals (UI) of the data waveform.

8. A method as claimed in claim 1 wherein number of test samples in the set is 32.

9. A method as claimed claim 1 wherein the adjusting comprises incrementing and decrementing a gain level value that controls the gain applied by the amplifier.

10. A data receiver comprising:
an amplifier connected to receive a data waveform and to amplify it, the amplifier having a controllable gain,
a test sampler connected to sample the amplified data waveform to a 1 or 0 based on a reference level, to provide a set of test bits, and
a gain adjusting circuit responsive to the number of test bits that are one of 1 or 0 in the set of the test bits.

11. A receiver circuit as claimed in claim 10 wherein the gain adjusting circuit comprises:
a population counter connected to receive the test bits of the set and to provide a count of the test bits of the set that are one of 1 or 0,
a cross coder connected to receive the count and convert it to increment and decrement signals, and
a gain level register connected to receive the increment and decrement signals, being responsive thereto to increment and decrement its value,
wherein an output of the gain level register is connected to control the gain of the amplifier.
